(19) United States
(12) Patent Application Publication
(10) Pub. No.: US 2026/0164698 A1
(43) Pub. Date: Jun. 11, 2026

(54) 2D METAL SELENIDE-SILICON STEEP SUB-THRESHOLD HETEROJUNCTION TRIODES WITH HIGH ON-CURRENT DENSITY

(71) Applicant: THE TRUSTEES OF THE UNIVERSITY OF PENNSYLVANIA, Philadelphia, PA (US)

(72) Inventors: Deep JARIWALA, Philadelphia, PA (US); Jinshui MIAO, Philadelphia, PA (US)

(21) Appl. No.: 18/708,671

(22) PCT Filed: Nov. 9, 2022
(86) PCT No.: PCT/US2022/079561

§ 371 Date: May 9, 2024

Related U.S. Application Data
(60) Provisional application No. 63/277,250, filed on Nov. 9, 2021.

(51) Int. Cl. H10D 30/47; H10D 64/68

(52) U.S. Cl. CPC H10D 30/481; H10D 64/691

(57) ABSTRACT

A tunnelling field-effect transistor, comprising: an active portion comprising one or more layers of a 2-D crystalline material; a semiconducting substrate, the active portion being superposed over the semiconducting substrate, and the semiconducting substrate being 3-D crystalline in nature; a source electrode in electronic communication with the active portion; a drain electrode in electronic communication with the active portion; and a gate electrode. Methods, comprising operating a transistor according to the present disclosure. Devices, a device comprising a transistor according to the present disclosure, the device optionally being characterized as a logic device. Methods, the methods comprising fabricating a transistor according to the present disclosure.

### CROSS-REFERENCE TO RELATED APPLICATIONS

The present application claims priority to and the benefit of U.S. patent application No. 63/277,250, “2D Metal Selenide-Silicon Steep Sub-Threshold Heterojunction Triodes with High On-Current Density” (filed Nov. 9, 2021), the entirety of which application is incorporated herein by reference for any and all purposes.

### GOVERNMENT RIGHTS

This invention was made with government support under FA9550-21-1-0035 awarded by the Air Force Research Laboratory. The government has certain rights in the invention.

### TECHNICAL FIELD

The present disclosure relates to the field of electronic devices and to the field of heterojunction transistors.

### BACKGROUND

Dimensional scaling of metal-oxide semiconductor field-effect transistors (MOSFETs) has continued over the past decade despite diminishing returns in terms of improving packing density. A side effect of improving packing density has been power dissipation which comprises the central problem is modern, highly scaled nanoelectronics^{1,2}. However, a fundamental limit on subthreshold swing (SS) in thermionic devices involving single band transport such as MOSFETs not only restricts further scaling in power consumption and supply voltage but also increases power density and dissipation in MOSFET-based circuits. This limitation on SS is set at m*ln(10)k_{b}T/q (˜60 mV/decade at room temperature for an ideal MOSFET)¹⁰, where k_{b} is Boltzmann constant, m is the ideality factor (=1 for an ideal transistor), q is the elementary charge and T is temperature, arises from thermal nature of carrier injection at the metal semiconductor contact that puts a lower limit on the power consumed per switching cycle.

To overcome this limitation tunneling field-effect transistors (TFETs), whose operation relies on band-to-band tunneling rather than thermionic emission, have appeared as a promising alternative to modern MOSFETs for low-power electronics.^{3,4} However, TFETs have long been limited by low ON/OFF ratios for <60 mV/dec operation and net ON current density.^{2,3} Accordingly, there is a long-felt need in the art for improved TFET devices.

### SUMMARY

Low power consumption in both static and dynamic modes of operation is a key requirement in modern, highly scaled nanoelectronics. Tunneling field-effect transistors (TFETs) that exploit direct band-to-band tunneling of charges and exhibit steep sub-threshold slope (SS) transfer characteristics are an attractive option in this regard. However, current generation of Si and III-V heterojunction based TFETs while suffer from low ON current density and ON/OFF current ratios for <60 mV/dec operation. Semiconducting two-dimensional (2D) layers have recently renewed enthusiasm in novel device design for TFETs not only because of their atomically-thin bodies that favor superior electrostatic control but the same feature also favors higher ON current density and consequently high ON/OFF ratio. Here, we demonstrate gate-tunable heterojunction diodes (triodes) fabricated from InSe/Si 2D/3D van der Waals heterostructures, with a minimum subthreshold swing (SS) as low as 6.4 mV/dec and an SS average of 30 mV/dec over 4 decades of current. Further, the devices show a large current on/off ratio of approximately 106 and on-state current density of 0.3 μA/μm at a drain bias of −1V. Our work opens new avenues for 2D semiconductors for 3D hetero-integration with Si to achieve ultra-low power logic devices.

In meeting the described challenges, the present disclosure provides a tunnelling field-effect transistor, comprising: an active portion comprising one or more layers of a 2-D crystalline material; a semiconducting substrate, the active portion being superposed over the semiconducting substrate, and the semiconducting substrate being 3-D crystalline in nature; a source electrode in electronic communication with the active portion; a drain electrode in electronic communication with the active portion; and a gate electrode.

Also provided are methods, comprising operating a transistor according to the present disclosure, e.g., according to any one of Aspects 1-17.

Further disclosed are devices, a device comprising a transistor according to the present disclosure (e.g., according to any one of Aspects 1-17), the device optionally being characterized as a logic device.

Additionally provided are methods, the methods comprising fabricating a transistor according to the present disclosure, e.g., according to any one of Aspects 1-17.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various aspects discussed in the present document. In the drawings:

FIG. 1. 2D/3D heterojunction triode device structure and characterizations. (a) Schematic layout of an InSe/p⁺⁺Si 2D/3D heterojunction TFET. (b) Optical micrograph of a representative 2D/3D heterojunction TFET showing InSe/Si 2D/3D heterostructure, AlOₓ gate dielectric, and metallic electrodes. Scale bar, 5 μm. (c) Bright-field STEM image showing the cross-sectional architecture of the device. (d-e) Zoom-in images showing the layered crystalline structure of InSe and a 2 nm-thick amorphous native silicon oxide (SiOx) between InSe and single crystalline Si. (f) Atomic resolution HAADF-STEM image overlapped with projected atomic model showing good match with the g-InSe polytype.

FIG. 2. Room-temperature electrical characteristics and band diagrams of InSe/Si heterojunction triodes. (a) Logarithmic-scale I_{DS}-V_{GS} transfer characteristics of InSe/Si heterojunction triode devices measured at room-temperature with applied V_{DS}=−0.5 V (black) and −1.0 V (red) plots. The minimum sub-threshold swing (SS) value is 6.4 mV/decade. The green line represents gate leakage current of ˜10⁻¹³ A/μm. (b) Zoom in I_{DS}-V_{GS} transfer characteristics (blue dashed box in panel a) showing V_{GS} sweep from −6.0 to −5.8 V. The hypotenuse of right triangle is a reference for indicating the thermionic limit of 60 mV/decade for the SS. (c) Linear-scale I_{DS}-V_{GS} transfer characteristics of the same InSe/Si heterojunction device. The inset indicates the transconductance of I_{DS}-V_{GS} transfer curves. The transconductance shows a maximum at −5.8 V. (d) Predicted transfer characteristics of InSe/Si heterojunction triode devices using TCAD simulator. Inset shows zoom in predicted transfer characteristics using Sentaurus TCAD simulator. (e) Simulated equilibrium band diagram at zero drain and gate bias with the three materials at the junction indicated by blue (InSe), orange (SiO₂) and red (Si) colors respectively while the red and blue lines indicate maxima and minima of conduction bands respectively. (f) Simulated band diagrams of ON (top) and OFF (bottom) states with the purple and green dashed lines representing quasi fermi levels for electrons and holes respectively.

FIG. 3. (a) Logarithmic-scale I_{DS}-V_{GS} transfer characteristics comparison between the InSe FETs measured at V_{DS}=1V and heterojunctions at V_{DS}=−1V, both at room temperature. (b) Subthreshold swing comparison of InSe/Si heterojunction FETs with control InSe FETs. The minimum SS value of control InSe FETs is around 90 mV/decade. The InSe/Si heterojunction FETs show sub-60 mV/decade over 4-5 decades of drain current. The blue dashed line represents the thermionic limit of 60 mV/decade. (c) Linear-scale I_{DS}-V_{DS} output characteristics of control InSe FETs measured at room temperature with V_{GS} varying from −6 to 6V in 1V steps. Inset shows a zoom in on the same plot closer to origin to show linearity of the characteristics. (d) Linear-scale I_{DS}-V_{DS} output characteristics of InSe/Si heterojunctions measured at room temperature with V_{GS} sweeping from −6 to 6V with 1 V step. The inset is the same plot on a logarithmic current-axis.

FIG. 4. Temperature-dependent electrical characteristics of InSe/Si 2D/3D triodes. (a) Temperature-dependent I_{DS}-V_{GS} transfer characteristics measured at V_{DS}=−2.0 V. (b) Arrhenius plot of drain current as a function of 1000/T for various gate voltages. (c) Subthreshold swing as a function of temperature for InSe/Si 2D/3D heterojunction tunneling triodes and InSe control MOSFETs.

FIG. 5. Performance comparison of the InSe/Si 2D/3D HJ-TFETs with reported subthermionic HJ-TFETs and NC-FETs. (a) Subthreshold swing as a function of drain current for various types of subthermionic FETs. The black dashed line represents the SS=60 mV/decade limit. The red squares represent the SS values of InSe/Si HJ-TFETs in this work. The InSe/Si heterojunction devices show SS below 60 mV/decade for 4-5 orders of magnitude of drain current, with a minimum of around 6 mV/decade. (b) Average SS versus drain current where SS becomes lower than 60 mV/decade. Here, SS_{average} of InSe/Si covers >4 decades of I_{DS} (red), SS_{average} of MoS₂/Ge covers >4 decades (navy), SS_{average} of InAs/Si covers ˜4 decades (blue), SS_{average} of MoS₂/Si covers <1 decade (green), SS_{average} of NC-MoS₂ covers ˜3 decades (orange). (c) I₆₀/I_{OFF} for various subthermionic devices. The I₆₀/I_{OFF} ratio of InSe/Si HJ-TFETs is >10⁴.

FIG. 6. Photoemission spectra from bulk InSe crystals with various doping conditions. The Ef-VBM energies are shown.

FIG. 7. Cross sectional composition analysis of the InSe/Si heterojunction triode device. a. Bright field cross section micrograph of the device showing various layers in the heterojunction and the gate stack. A ˜2 nm thick SiOx layer is identified at the interface between InSe and Si. b. Line cuts of composition as a function of depth of the device from the top for oxygen (blue) and silicon (green). The clear peak in oxygen at the start of Si edge shows the presence of a thin sub-oxide layer. c. Composition line profiles for all relevant elements indicating the appropriate layer thicknesses and compositions.

FIG. 8. a. Experimentally measured electron diffraction pattern of gamma (γ) phase InSe along [100] direction. b. Simulated electron diffraction pattern that matches the experiment. Without being bound to any particular theory, these results suggest that the crystal flake used in the devices may be gamma (γ) phase InSe.

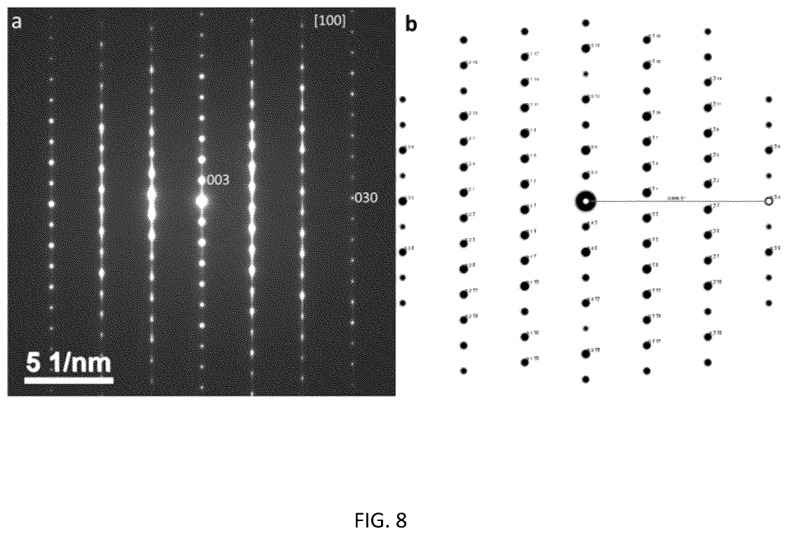

FIG. 9. Band diagram representation of the InSe/Si 2D/3D tunneling FET at room temperature and various doping levels and species. The degenerately doped Si acts as the source and the InSe is the drain. (a) Lightly P-doped. (b) Heavily P-doped. (c) Lightly N-doped. (d) Heavily N-doped.

FIG. 10. a. Simulated transfer characteristics of the InSe—Si heterojunction triodes at various drain voltages showing SS<60 mV/dec. b. Simulation of the linear-scale I_{DS}-V_{DS} output characteristics of InSe/Si heterojunction device at room temperature and various V_{GS} values. The SiO₂ layer thickness set to 2 nm in this simulation.

FIG. 11. WSe₂/P⁺⁺ Si heterojunction tunnel field-effect transistors (T-FET) and their electrical characterizations. (a) Optical micrograph of a representative WSe₂/p⁺⁺ Si 2D/3D heterojunction T-FET device. Scale bar: 10 um. (b) Logarithmic-scale I_{DS}-V_{GS} transfer characteristics of WSe₂/p⁺⁺ Si heterojunction TFET measure at V_{DS}=−0.5 V. (c) Zoom in I_{DS}-V_{GS} transfer characteristics of WSe₂/p⁺⁺ Si heterojunction devices measured at room temperature with applied V_{DS}=−0.5 V (black) and −1.0 V (red) plots. The minimum sub-threshold swing (SS) value is 32.7 mV/dec. (d) Subthreshold swing as a function of gate voltage (V_{GS}) with applied V_{DS}=−0.5 V (blue) and −1.0 V (orange) plots. The black dashed line shows the thermionic limit of 60 mV/dec.

FIG. 12. InSe field-effect transistor characterizations at room temperature. (a) Logarithmic-scale and (b) linear-scale I_{DS}-V_{GS} transfer characteristics of InSe FET measure at V_{DS}=1.5 V (red) and 1.0 V (blue). (c) Subthreshold swing as a function of gate voltage (V_{GS}) with different applied V_{DS} plots. The black dashed line shows the thermionic limit of 60 mV/dec at room temperature.

FIG. 13. InSe field-effect transistors characterizations. (a) Temperature-dependent logarithmic-scale and (b) linear-scale I_{DS}-V_{GS} transfer characteristics of InSe FET measure at V_{DS}=−1.5 V. A clear decrease in both SS and on current is observed. The decrease in SS suggests thermionic transport while the decrease in ON current suggests imperfect contacts with a thermal barrier between the metal and the semiconductor.

FIG. 14. Room-temperature electrical characteristics of InSe/Si heterojunction field-effect transistors (TFET). (a) Logarithmic-scale I_{DS}-V_{GS} transfer characteristics of InSe/Si heterojunction TFET measured at different V_{DS}. The blue line represents gate leakage current of around 10⁻¹² A. (b) Linear-scale I_{DS}-V_{GS} transfer characteristics measured at different V_{DS}. (c) Subthreshold swing as a function of drain current (I_{DS}) with different applied V_{DS} plots. The black dashed line shows the thermionic limit of 60 mV/dec.

### DETAILED DESCRIPTION OF ILLUSTRATIVE EMBODIMENTS

The present disclosure may be understood more readily by reference to the following detailed description of desired embodiments and the examples included therein.

Unless otherwise defined, all technical and scientific terms used herein have the same meaning as commonly understood by one of ordinary skill in the art. In case of conflict, the present document, including definitions, will control. Preferred methods and materials are described below, although methods and materials similar or equivalent to those described herein can be used in practice or testing. All publications, patent applications, patents and other references mentioned herein are incorporated by reference in their entirety. The materials, methods, and examples disclosed herein are illustrative only and not intended to be limiting.

The singular forms “a,” “an,” and “the” include plural referents unless the context clearly dictates otherwise.

As used in the specification and in the claims, the term “comprising” may include the embodiments “consisting of” and “consisting essentially of” The terms “comprise(s),” “include(s),” “having,” “has,” “can,” “contain(s),” and variants thereof, as used herein, are intended to be open-ended transitional phrases, terms, or words that require the presence of the named ingredients/steps and permit the presence of other ingredients/steps. However, such description should be construed as also describing compositions or processes as “consisting of” and “consisting essentially of” the enumerated ingredients/steps, which allows the presence of only the named ingredients/steps, along with any impurities that might result therefrom, and excludes other ingredients/steps.

As used herein, the terms “about” and “at or about” mean that the amount or value in question can be the value designated some other value approximately or about the same. It is generally understood, as used herein, that it is the nominal value indicated ±10% variation unless otherwise indicated or inferred. The term is intended to convey that similar values promote equivalent results or effects recited in the claims. That is, it is understood that amounts, sizes, formulations, parameters, and other quantities and characteristics are not and need not be exact, but can be approximate and/or larger or smaller, as desired, reflecting tolerances, conversion factors, rounding off, measurement error and the like, and other factors known to those of skill in the art. In general, an amount, size, formulation, parameter or other quantity or characteristic is “about” or “approximate” whether or not expressly stated to be such. It is understood that where “about” is used before a quantitative value, the parameter also includes the specific quantitative value itself, unless specifically stated otherwise.

Unless indicated to the contrary, the numerical values should be understood to include numerical values which are the same when reduced to the same number of significant figures and numerical values which differ from the stated value by less than the experimental error of conventional measurement technique of the type described in the present application to determine the value.

All ranges disclosed herein are inclusive of the recited endpoint and independently of the endpoints (e.g., “between 2 grams and 10 grams, and all the intermediate values includes 2 grams, 10 grams, and all intermediate values”). The endpoints of the ranges and any values disclosed herein are not limited to the precise range or value; they are sufficiently imprecise to include values approximating these ranges and/or values. All ranges are combinable.

As used herein, approximating language may be applied to modify any quantitative representation that may vary without resulting in a change in the basic function to which it is related. Accordingly, a value modified by a term or terms, such as “about” and “substantially,” may not be limited to the precise value specified, in some cases. In at least some instances, the approximating language may correspond to the precision of an instrument for measuring the value. The modifier “about” should also be considered as disclosing the range defined by the absolute values of the two endpoints. For example, the expression “from about 2 to about 4” also discloses the range “from 2 to 4.” The term “about” may refer to plus or minus 10% of the indicated number. For example, “about 10%” may indicate a range of 9% to 11%, and “about 1” may mean from 0.9-1.1. Other meanings of “about” may be apparent from the context, such as rounding off, so, for example “about 1” may also mean from 0.5 to 1.4. Further, the term “comprising” should be understood as having its open-ended meaning of “including,” but the term also includes the closed meaning of the term “consisting.” For example, a composition that comprises components A and B may be a composition that includes A, B, and other components, but may also be a composition made of A and B only. Any documents cited herein are incorporated by reference in their entireties for any and all purposes.

2D semiconductors have recently renewed opportunity in TFET device design because of their atomically-thin nature that permits strong electrostatic control.⁴⁻⁹ This electrostatic control not only allows smaller SS values in TFETs but may also permit higher ON/OFF ratios by maximizing ON current. In addition, 2D materials are naturally self-passivated, which allows them to be easily embedded between metal gates and thin dielectrics for enabling strong electrostatic modulation. But stable and complementary doping in 2D materials remains a persistent challenge,^{11,12} unlike in 3D bulk materials which have well-established, complementary doping schemes. TFETs device structures normally comprise of p-i-n homo or heterojunctions where the i (intrinsic) layer undergoes strong electrostatic modulation and shrinkage in lateral dimensions to permit direct band-to-band tunneling. In the case of intrinsic 2D materials this electrostatic modulation is relatively easy to achieve. Therefore, combining 2D materials with 3D bulk semiconductors offers an interesting avenue¹³⁻¹⁵ for not only exploring novel TFET architectures but also exploring other advantages such a large current modulation via electrostatic gating. Here, we demonstrate unintentionally n-doped 2D-InSe and heavily p doped (p++) 3D-silicon-based gate-tunable heterojunction diodes (triodes) that overcome the thermionic limitation of conventional MOSFETs and achieve a minimum SS of 6.4 mV/decade as well as an average SS of 34 mV/decade over four orders of magnitude of drain current, simultaneously with an ON current density of 0.3 uA/um.

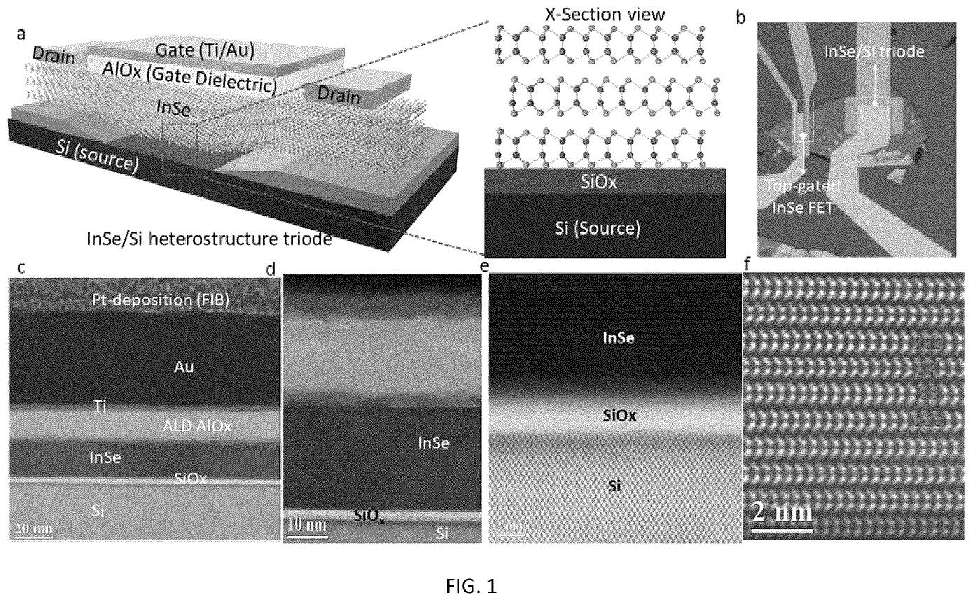

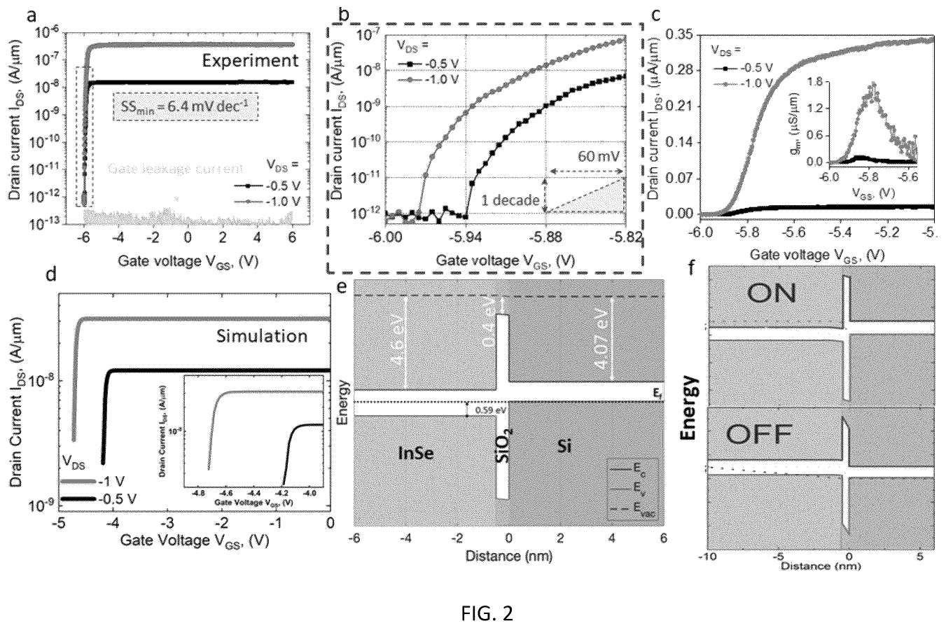

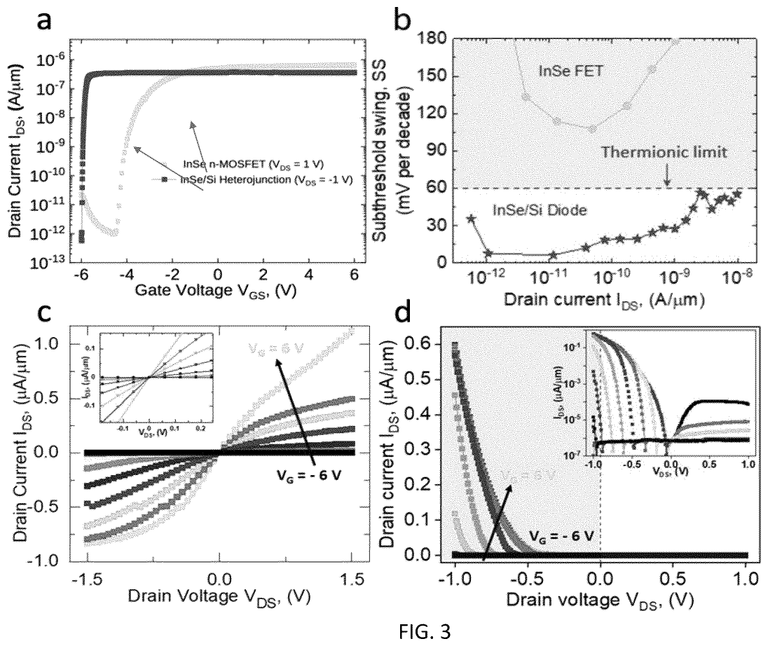

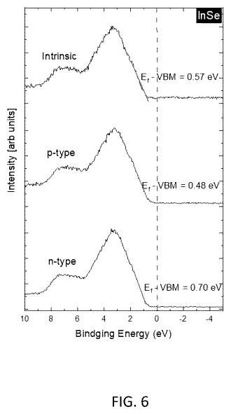

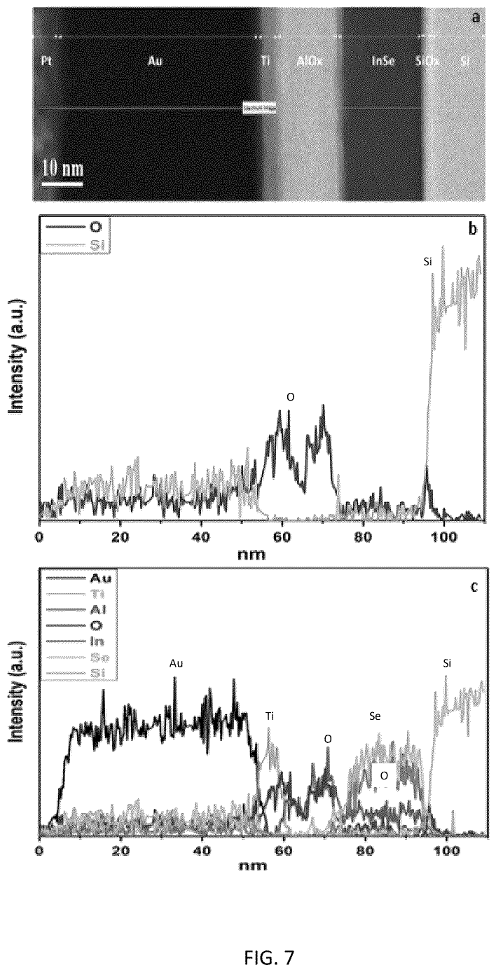

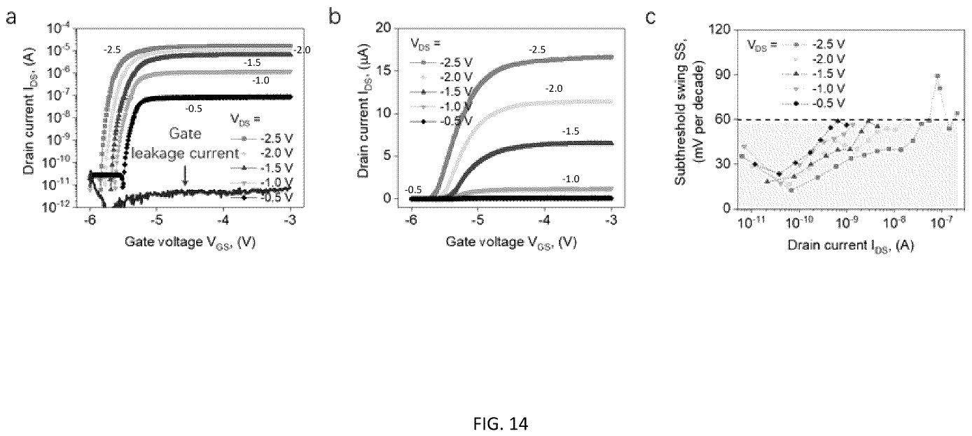

We perform electrical characterization of the InSe/Si heterojunction triode in a three-terminal transistor configuration at room temperatures. The device exhibits a small SS value of 6.4 mV/decade with a current on-off ratio of 10⁶, as well as a large on-state current density of 0.3 μA/μm at an applied V_{DS}=−1 V (FIG. 2a). As compared to the drain current the gate-leakage current density shows negligible magnitude at ˜10⁻¹³ A/um. FIG. 2b represents the zoom in transfer characteristics with V_{GS} changing from −6 to −5.82 V showing the steepness in context of a magnified x-axis. It is worth noting that a gate voltage change of mere 180 mV modulates the output current by over five orders of magnitude. The same device shows a peak transconductance of 1.8 μS/μm for V_{DS}=−1 V, as displayed in FIG. 2c along with the linear-scale I_{DS}-V_{GS} transfer characteristics. We note that this phenomenon is not observed in a one-off device and has been reproducible in other devices (FIG. 14). To understand the details of the device electronic structure, we have performed photoemission and Hall measurements on our InSe crystals used to determine the carrier density and band alignment. Using these values combined with the known gap value of gamma phase InSe, we simulate band diagrams of near intrinsic to unintentionally n-doped InSe/p++Si heterojunction triodes with an intermediate SiO₂ layer. We note that the exact structure, composition, and nature of this SiO₂ layer is unclear and hence modelled purely as a perfect insulator in these simulations with no traps or other leakage mechanisms present. Additional details on the composition of this SiO₂ interlayer are provided in FIG. 7. Our simulated I_{DS}-V_{GS} characteristics (FIG. 2d) show qualitative resemblance to the experimental plots as shown in FIG. 2 a-b. Although the threshold and ON/OFF ratio do not match quantitatively, they are likely to vary since no trap charges at either interface have been considered in the simulation (See Section S2 for simulation details). None the less the SS (<40 mV/dec) from simulated plots (see Section S2), are reasonably matched to our experimentally made devices. Equilibrium band diagrams with known electron affinities and carrier concentrations shows that the InSe/SiO₂/Si form a type II junction with 0.59 eV valence band offset that is closely matched with photoemission results (See FIG. 6) Simulated band diagrams of the device are also obtained in the ON and OFF states by varying the carrier density in InSe representing modulated gate bias (FIG. 2 f top and bottom respectively) at a fixed drain bias of −1 V. As InSe is doped with a gate voltage the conduction band of InSe overlaps with the heavily populated valence band and doping impurity band of Si resulting is direct tunneling through the SiO₂ insulator. To further evaluate the electrical characteristics of our devices we make comparison with control top gated InSe MOSFETs made on the same InSe crystal as the junction as shown in FIG. 1b. We observe clear and stark differences between the two devices made from the same flake (crystal), which may (without being bound to any theory) suggest that our heterojunction device indeed has a different charge transport mechanism i.e., BTBT. There are three clear differences observed between the control InSe FET and the InSe/Si heterojunction triode:
1. The current density of InSe MOSFET is higher than the InSe/Si heterojunction FET.
2. The average SS value in transfer characteristics of InSe FETs is more than three times lower for same oxide thickness. (FIG. 3 a-b)
3. The InSe FETs have linear output characteristics while the InSe/Si heterojunctions clearly show rectifying output with gate-tunable rectification (FIG. 3 c-d). First the transfer characteristics when compared over the same scale (FIG. 3a) show that the InSe MOSFET (green) is clearly less steep in the sub-threshold region as compared to the InSe/Si heterojunction (blue). Further, one can see from the same plot that the InSe MOSFET has higher current density in the ON state as opposed to InSe/Si heterojunction triode. Both devices show comparatively flat ON state characteristics in the semi-log scale which further suggests that the InSe/Si heterojunction can provide large swings in current with small swings in voltage and suitable for low-voltage operation. Further, taking an average slope of these I_{DS}-V_{GS} transfer characteristics and plotting against the drain current density we find that the InSe MOSFET has SS value that hits a minimum at ˜100 mV/dec and rapidly rises with both increase of decrease in current (See section S4). In contrast, the InSe/Si heterojunction FET shows a small SS value ranging from 6.4 to 60 mV/dec over 4 orders of magnitude change in current with an average of ˜30 mV/dec. These average SS values have been derived using the data points of drain current in the 10⁻¹² to 10⁻⁸ A/μm range. Without being bound to any theory, this may be because the InSe used in our devices can be unintentionally doped and near intrinsic in nature and therefore likely to show p-type conduction upon further increase in V_{GS} in the negative direction (FIG. 3a, green curve from −4 to −6 V). We have also made control MOSFET and InSe/Si heterojunction triode devices with substitutionally p-doped and n-doped InSe crystals (See supplementary information table 1). Neither the MOSFETs nor the heterojunctions based on intentionally doped InSe show such steep SS response as a function of gate voltage which suggests that purity/cleanliness of the crystal near band edges may relate to the reported steep SS behavior.

Another notable difference between the InSe MOSFETs and InSe/Si heterojunction triodes is in the output (I_{DS}-V_{GS}) characteristics. The InSe MOSFETs with Ohmic contacts show highly symmetric I-V characteristics above the origin with early signs of saturation (FIG. 3c). These characteristics are representative of n-MOSFET with increasing conductance (slope) and hence current as a function of gate voltage from −6 V to 6 V in agreement with the transfer characteristics in FIG. 3a. Even when magnified to small values of voltage (FIG. 3c inset) these I-V curves remain linear suggesting ohmic nature of the contacts. In contrast, the InSe/Si heterojunction triode clearly demonstrates rectifying IV characteristics (FIG. 3d). Not only are the characteristics rectifying but the turn on voltage of the diode is tunable as a function of gate voltage. This observation is like that of several prior reports of gate-tunable p-n diodes based on 2D materials¹⁶⁻¹⁸. When observed on a logarithmic current scale (FIG. 3d, inset), the shift in turn on voltage and rise in reverse current is clear. We have evaluated these output characteristics of the heterojunction as a function of doping levels in InSe via TCAD simulations and they are in good qualitative agreement with our experimental observations (see Section S3)

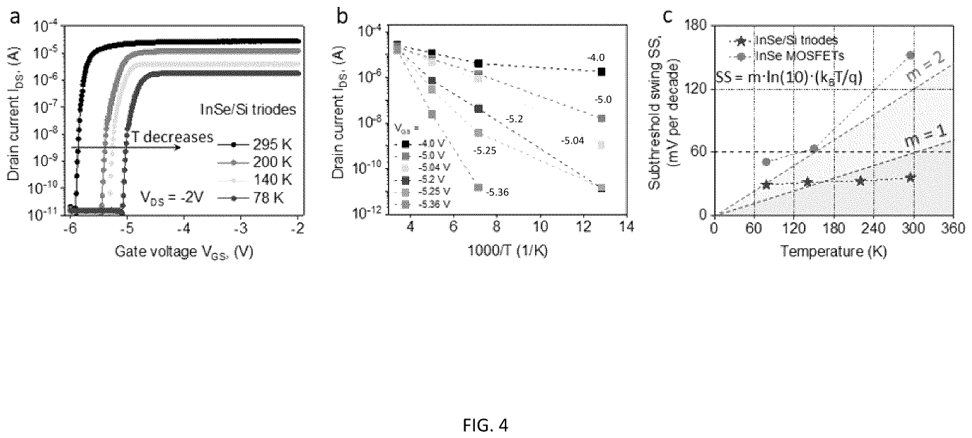

To show the differences between charge transport mechanism of the InSe MOSFETs and the InSe/Si heterojunction triodes, we perform temperature-dependent electrical characterization of the two devices as shown in FIG. 4. FIG. 4a shows the I_{DS}—V_{GS} characteristics of the heterojunction device at various temperatures for V_{DS}=−2 V. The threshold voltage for band-to-band tunneling (BTBT) appears to clearly shift right with reducing temperature. In addition, the magnitude of ON current plateau also appears to reduce with reducing temperatures. This suggests that the transport in these devices is complex and varies as a function of gate voltage/position of Fermi level in the InSe. Decrease in ON current as a function of T suggests some thermal barrier in the device. This thermal barrier could arise from multiple reasons ranging from imperfect metal InSe contacts to hopping transport in the non-junction part of the InSe^{19,20}. Another possible mechanism to explain this is trap-assisted tunneling, where electrons first tunnel into a trap within the band gap close to the conduction band, from which they are thermally excited into the conduction band. The Bridgman-grown InSe crystals^{21,22} possess interstitial atoms, vacancies and unintentional impurities. To understand this temperature activated transport in more detail we present Arrhenius plot analysis (FIG. 4b) which shows plots made for different gate voltages. We observe an activation energy of 0.2 eV extracted for the subthreshold region. Further this activation energy changes from 0.2 to 0.05 eV as the gate voltage changes from −5.36 to −4.0 V suggesting that the transport is weakly dependent on temperature in the high doping density (V_{GS}=−4 V). Given the steep drop in current and lack of ability to obtain currents below 10⁻¹¹ A, it can be challenging to ascertain the nature of temperature dependence in the sub-threshold region. However, it is well known for thermionic transport in conventional MOSFETs that the SS depends linearly on T as SS=m·ln(10)k_{b}T/q, where m is the ideality factor (˜1 for an ideal MOSFET). Upon plotting the SS slope as function of T we find that the slope is nearly independent of T in stark contrast with InSe MOSFET which shows as clear dependence on T with an m factor >2 (FIG. 4 c). This provides strong evidence that the observed transport at least in the steep SS range of our InSe—Si heterojunction triode devices is dominated by BTBT.

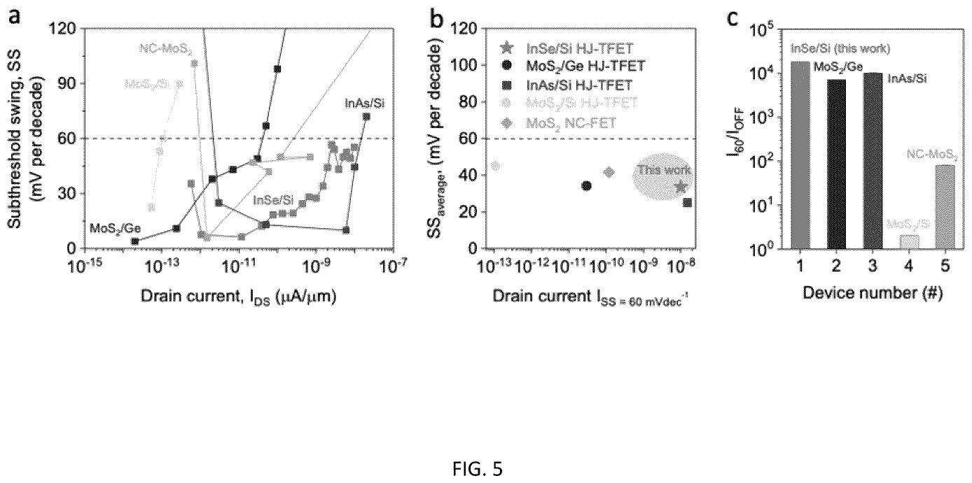

Finally, given the steep SS of our devices combined with the large ON/OFF ratio we perform benchmarking of our devices with literature precedent on select steep SS devices operating at room T. We compare our devices on three metrics: (i) SS vs Drain current density, (ii) Drain current at SS=60 mV/dec vs average SS and finally (iii) Current at SS=60 mV/dec vs OFF current. FIG. 5 shows values as a function of drain current for various steep SS TFET devices and negative capacitance FETs²³⁻²⁶. The SS versus I_{DS} for our device is extracted from the transfer curves in FIG. 2a. The comparison data clearly indicates that the InSe/Si TFETs simultaneously have small SS, high I₆₀ (current where SS becomes 60 mV/decade) and current density more than two orders of magnitude larger than that obtained in MoS₂/Ge TFET. I₆₀ is the chosen metric since the current saturates soon after that and would be point of operation of the ON state of the device.

In summary, we have demonstrated BTBT heterojunction field-effect transistors through vdW integration of 2D InSe on 3D silicon. Owing to the atomically thin nature of 2D InSe and fixed doping profile in 3D bulk silicon, bands can be effectively modulated by a capacitively coupled gate enabling strong modulation of band alignment resulting in direct BTBT. A minimum SS of 6.4 mV/dec with an average SS of 34 mV/decade over four decades of drain current at room T are reported in the as-fabricated InSe/Si 2D/3D heterojunction TFETs. In addition, the devices exhibit a high current on/off ratio of up to 10⁶ and on-state current density of 0.3 μA/μm at a V_{DS}=−1 V. Our results suggest that 2D/3D integration is a viable path towards ultra-low-power and highly scaled logic switches. Given that Indium has low solubility in Si²⁷ and InSe is lattice matched to Si [111]^{28,29}, our approach allows large area growth and scaling of high performance InSe/Si heterojunction triodes for enhanced digital logic.

### Methods

Device Fabrication: All devices were fabricated using electron beam lithography (EBL) using a three-step process. Electron-beam resist (PMMA) was first spin-coated onto the P⁺⁺ Si substrate (WaferPro, B doping with resistivity of 0.005 ohm·cm) capped with a 50-nm SiO₂ layer grown using dry oxidation process. Then, a square pattern (size: 10×10 ums) was defined by EBL (step 1), following by a development process. After that, the Si/SiO₂ substrate was immersed into a buffered oxide etch (BOE) solution for about 1 min to etch the SiO₂ layer exposing the lower Si layer. Finally, the rest of the resist was removed by acetone, and the as-prepared substrate was immediately transferred to the glove box to avoid reoxidation of the exposed Si window. In the glove box, a few-layer 2D InSe flake was physically transferred onto the exposed Si window. The flake was exfoliated using a tape from the bulk crystal and then stuck onto a polydimethoxysilane (PDMS) stamp (GelPak, A4). The metal electrode patterns of the devices were then defined by EBL (step 2), following by metal deposition and lift-off processes. After that, we use the atomic layer deposition (ALD) method to deposit a 10 nm-thick AlOₓ top-gate dielectric on InSe. The top-gate electrode was finally defined by EBL (step 3), metal deposition and lift-off processes.

### Growth and Characterization of InSe Crystals

InSe single crystals were grown by vertical Bridgman method using a non-stoichiometric polycrystalline In_{1.04}Se_{0.96} charge. n- and p-type doping was achieved by adding Sn (2 at. %) and Zn (as ZnSe, 0.3 at. %), respectively, during InSe charge synthesis. The InSe melt was equilibrated at 720° C. for several hours, then the ampoule was translated across a temperature gradient at a rate of 0.5 mm/h.

Electrical characterization: The electrical measurements for all devices were performed by a Lakeshore probe station combined with a Keithley 4200 semiconductor analyzer. All the measurements were carried out at room temperature unless noted in the figures.

Simulations: TCAD Device simulations were performed using Synopsys Sentaurus Device Package.

Electron microscopy characterization: Electron transparent cross-sectional sample was prepared with an FEI Nova NanoLab 600 DualBeam (SEM/FIB). An FEI Titan 80-300 probe-corrected STEM/TEM microscope operating at 300 keV was employed to acquire selected area electron diffraction patterns, STEM images and STEM EDS line-scan.

### REFERENCES

1 Iannaccone, G., Bonaccorso, F., Colombo, L. & Fiori, G. Quantum engineering of transistors based on 2D materials heterostructures. Nature Nanotechnology 13, 183-191, doi:https://doi.org/10.1038/s41565-018-0082-6 (2018).
2 Li, X. et al. in Beyond-CMOS Technologies for Next Generation Computer Design (eds Rasit O. Topaloglu & H. S. Philip Wong) 195-230 (Springer International Publishing, 2019).
3 Lu, H. & Seabaugh, A. Tunnel Field-Effect Transistors: State-of-the-Art. IEEE Journal of the Electron Devices Society 2, 44-49, doi:10.1109/JEDS.2014.2326622 (2014).
4 Fiori, G. et al. Electronics based on two-dimensional materials. Nature Nanotechnology 9, 768-779, doi:10.1038/nnano.2014.207 (2014).
5 Yan, X. et al. Tunable SnSe2/WSe2 Heterostructure Tunneling Field Effect Transistor. Small 13, doi:10.1002/smll.201701478 (2017).
6 T, R. et al. Dual-gated MoS2/WSe2 van der Waals tunnel diodes and transistors. ACS nano 9, doi:10.1021/nn507278b (2015).
7 Britnell, L. et al. Field-Effect Tunneling Transistor Based on Vertical Graphene Heterostructures. Science 335, doi:10.1126/science.1218461 (2012).
8 Nourbakhsh, A., Zubair, A., Dresselhaus, M. S. & Palacios, T. Transport Properties of a MoS2/WSe2 Heterojunction Transistor and Its Potential for Application. Nano Letters 16, 1359-1366, doi:10.1021/acs.nanolett.5b04791 (2016).
9 Kim, S. et al. Thickness-controlled black phosphorus tunnel field-effect transistor for low-power switches|Nature Nanotechnology. Nature Nanotechnology 15, 203-206, doi:10.1038/s41565-019-0623-7 (2020).
10 Vandenberghe, W. G. et al. Figure of merit for and identification of sub-60 mV/decade devices. Applied Physics Letters 102, doi:10.1063/1.4773521 (2013).
11 Lv, R. et al. Two-dimensional transition metal dichalcogenides: Clusters, ribbons, sheets and more. Nano Today 10, 559-592 (2015).
12 K. S., N., A., M., A., C. & A. H., C. N. 2D materials and van der Waals heterostructures. Science 353, doi:10.1126/science.aac9439 (2016).
13 Bae, S.-H. et al. Integration of bulk materials with two-dimensional materials for physical coupling and applications. Nature Materials 18, 550-560, doi:https://doi.org/10.1038/s41563-019-0335-2 (2019).
14 Akinwande, D. et al. Graphene and two-dimensional materials for silicon technology. Nature 573, 507-518, doi:https://doi.org/10.1038/s41586-019-1573-9 (2019).
15 D, J., T. J., M. & M. C., H. Mixed-dimensional van der Waals heterostructures. Nature materials 16, 170-181, doi:10.1038/nmat4703 (2017).
16 Miao, J. et al. Gate-Tunable Semiconductor Heterojunctions from 2D/3D van der Waals Interfaces. Nano Letters 20, 2907-2915, doi:10.1021/acs.nanolett.0c00741 (2020).
17 Murali, K., Dandu, M., Das, S. & Majumdar, K. Gate-Tunable WSe2/SnSe2 Backward Diode with Ultrahigh-Reverse Rectification Ratio. Applied Material Interfaces 10, 5657-5664, doi:10.1021/acsami.7b18242 (2018).
18 Wang, C. et al. Gate-tunable diode-like current rectification and ambipolar transport in multilayer van der Waals ReSe2/WS2 p-n heterojunctions. Physical Chemistry Chemical Physics 18, 27750-27753, doi:10.1039/C6CP04752A (2016).
19 Sangwan, V. K. & Hersam, M. C. Electronic Transport in Two-Dimensional Materials. Annual Review of Physical Chemistry 69, 299-325, doi:10.1146/annurev-physchem-050317-021353 (2018).
20 Jariwala, D. et al. Band-like transport in high mobility unencapsulated single-layer MoS2 transistors. Applied Physics Letters 102, doi:10.1063/1.4803920 (2013).
21 Martinez-Pastor, J., Segura, A., Julien, C. & Chevy, A. Shallow-donor impurities in indium selenide investigated by means of far-infrared spectroscopy. Physical Review B 46, 4607 (1992).
22 Hopkinson, D. G. et al. Formation and healing of defects in atomically thin GaSe and InSe. ACS nano 13, 5112-5123 (2019).
23 Sarkar, D. et al. A subthermionic tunnel field-effect transistor with an atomically thin channel. Nature 526, 91-95, doi:doi:10.1038/nature15387 (2015).
24 Si, M. et al. Steep-slope hysteresis-free negative capacitance MoS2 transistors. Nature Nanotechnology 13, 24-28, doi:doi:10.1038/s41565-017-0010-1 (2018).
25 Tomioka, K., Yoshimura, M. & Fukui, T. in Symposium on VLSI Technology (VLSIT) 47-48 (2012).
26 Hyuk Shin, G. et al. Vertical-Tunnel Field-Effect Transistor Based on a Silicon-MoS2 Three-Dimensional-Two-Dimensional Heterostructure. 10, 40212-40218, doi:10.1021/acsami.8b11396 (2018).
27 Keck, P. H. & Broder, J. The Solubility of Silicon and Germanium in Gallium and Indium. Physical Review 90, doi:10.1103/PhysRev.90.521 (1953).
28 Higashi, G. S., Becker, R. S., Chabal, Y. J. & Becker, A. J. Comparison of Si(111) surfaces prepared using aqueous solutions of NH4F versus HF. Applied Physics Letters 58, 1656, doi:10.1063/1.105155 (1991).
29 O. Madelung, U. R., M. Schulz. in Non-Tetrahedrally Bonded Elements and Binary Compounds I Vol. 41C (SpringerMaterials, 1998).

### Supporting Information/Supplemental Disclosure

Section S1: Hall effect measurements, photoemission and transmission electron microspectroscopy

1. Hall Measurements on InSe bulk crystals for various doping conditions.

Samples for Hall effect measurements were cleaved with a razor blade and cut into parallelepipeds with about 0.1 mm in thickness and 8 mm×8 mm in size. Ohmic contacts to InSe were made by soldering high-purity In. Hall effect measurements were carried out in the Van der Pauw geometry at room temperature.

TABLE 1
Summary of Hall effect measurements on InSe crystals.

| | Undoped InSe | n-doped InSe | p-doped InSe |
|---|---|---|---|
| Dopant, Concentration | n/a | Sn, 2.6 at. % | Zn (from ZnSe), |
| in the melt | | | 0.3 at. % |
| Carrier bulk | 3.16 · 10¹⁴ | 1.47 · 10¹⁶ | 7.9 · 10¹³ |
| concentration, cm⁻³ | | | |
| Hall Mobility, | 1390 | 616 | 43 |
| cm²/(V · s) | | | |

2. Photoemission measurements and X-TEM composition profile.

X-ray photoelectron spectroscopy was carried out on a Kratos AXIS Ultra using a monochromatic Al Kα (1486.6 eV) X-ray source. The voltage and emission current on the X-ray source was 12 keV and 10 mA respectively. Scans to determine the VBM were acquired taking 0.1 eV steps with 100 ms dwell time and a 10 eV pass energy. The VBM was determined by a linear extrapolation to the binding energy axis.

3. Details on Cross section cutting and milling as well as compositional and crystal structure analysis.

Section S2. TCAD simulation parameters and methods:

Synopsys Sentaurus Device was used for the TCAD simulation. Sentaurus Device predicts the behavior of devices by discretizing the device architecture and information to solve it in partial differential equation form. Our model starts with the 3D definition of the fabricated device geometry along with the location of the contacts and their applied voltage. A separate Physics section records the phenomena we wish to take into consideration, such as recombination and band-to-band tunneling. Finally, we instruct the model how to measure its simulated device-which predefined electrode to sweep over, over what range, using which equations, etc. The model can also plot a wide array of elements such as bandgaps, electron and hole distribution and current, electric potential among other things, all of which along the 3D direction of choice. Our model solves sets of coupled differential equations namely Poisson's equation, continuity equations for electrons and holes and current equations for electrons and holes in two dimensions.

The materials parameters used for the simulations are detailed in the table below.

TABLE 2
Junction Materials parameters for TCAD simulations

| Parameters | InSe | | Si | | SiO₂ | |
|---|---|---|---|---|---|---|
| Electron affinity | 4.6 | eV [symbol] | 4.0727 | eV [symbol] | 0.4 | eV [symbol] |
| Bandgap | 1.27 | eV [symbol] | 1.12416 [symbol] | | 9 [symbol] | |
| Permittivity | 7 [symbol] | | 11.7 [symbol] | | 3.9 [symbol] | |
| Anisotropic | undefined | | 11.7 [symbol] | | undefined | |
| permittivity | | | | | | |
| Lattice thermal | 0.259 | W/(K cm) [symbol] | 1.6964 | W/(K cm) [symbol] | 0.014 | W/(K cm) [symbol] |
| conductivity | | | | | | |
| Lattice heat capacity | 1.479 | J/(K cm\hat{ }3) [symbol] | 1.63 | J/(K cm\hat{ }3) [symbol] | 1.67 | J/(K cm\hat{ }3) |
| Effective mass | 0.18 [symbol] | | 0.36 [symbol] | | 0.3 [symbol] | |
| (DOS)_electron | | | | | | |
| Effective mass | 0.5 [symbol] | | 0.81 [symbol] | | 0.33 [symbol] | |
| (DOS)_hole | | | | | | |

[symbol]

indicates data missing or illegible when filed

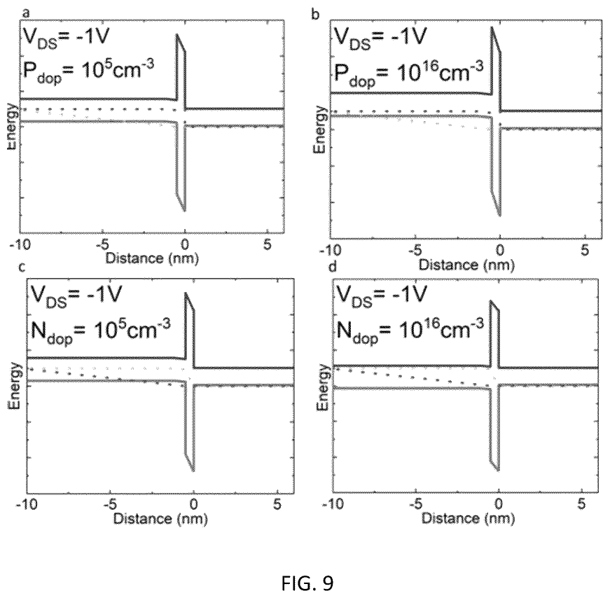

FIG. 9 represents the drain-to-source band-diagram of the InSe/Si 2D/3D heterojunction FET at different drain doping levels. For source region, degenerate p-type doping pins the Fermi level to the valence band. For the drain region, increasing boron doping raises the bands and causes the Fermi level to approach the conduction band, shown in FIG. 9 a and b. The inverse effect happens with arsenic doping (FIG. 9 c and d), which decreases the drain band level and causes the Fermi level to approach the valence band. This lowering facilitates the tunneling of electrons from source to drain, as represented by the black arrow in FIG. 9d. The heavier the doping, the easier it is for the electrons to overcome the oxide barrier and tunneling to occur.

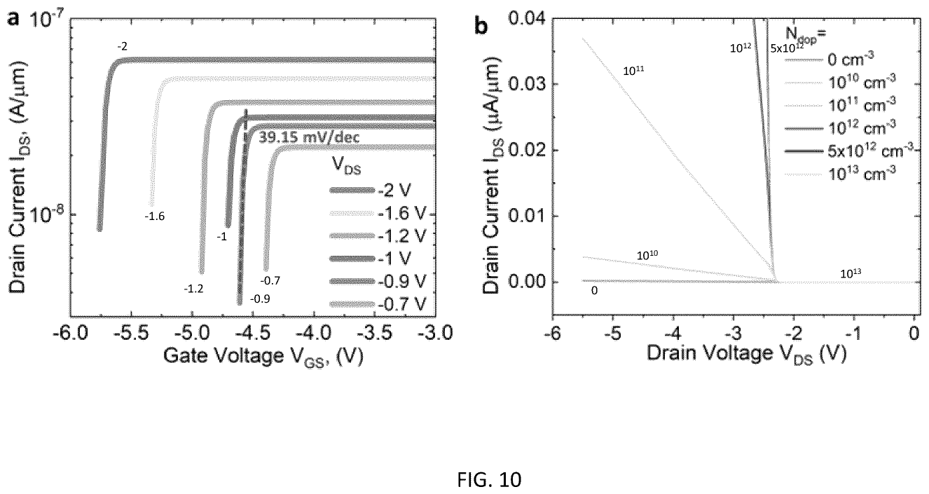

The simulations in FIG. 10 accurately predict the qualitative behavior observed in FIG. 2d and FIG. 3d respectively.

Section S3. Electrical Characteristics of WSe₂/Si P⁺⁺ heterojunctions.

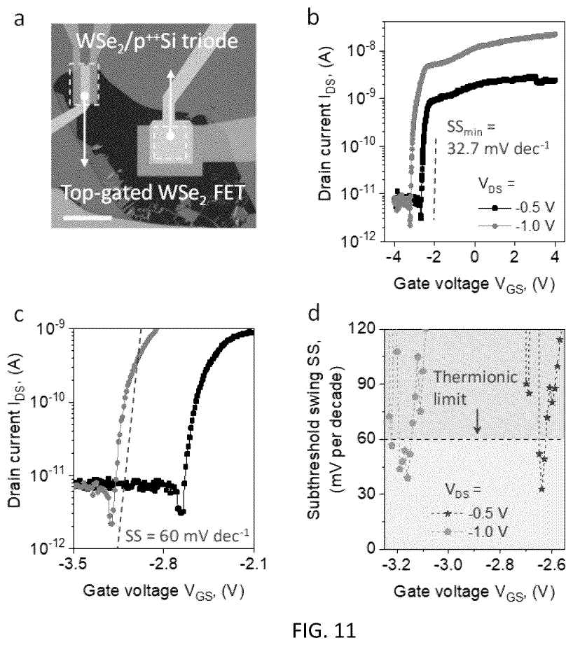

Devices were also made from WSe₂ and Si P⁺⁺ wafers using exactly the same procedure as outlined for InSe based devices. The bulk crystals of WSe₂ were purchased from HQ graphene. Control WSe₂ FETs were also fabricated from the same flakes which show SS values >100 mV/dec. across all range of currents. See FIG. 11.

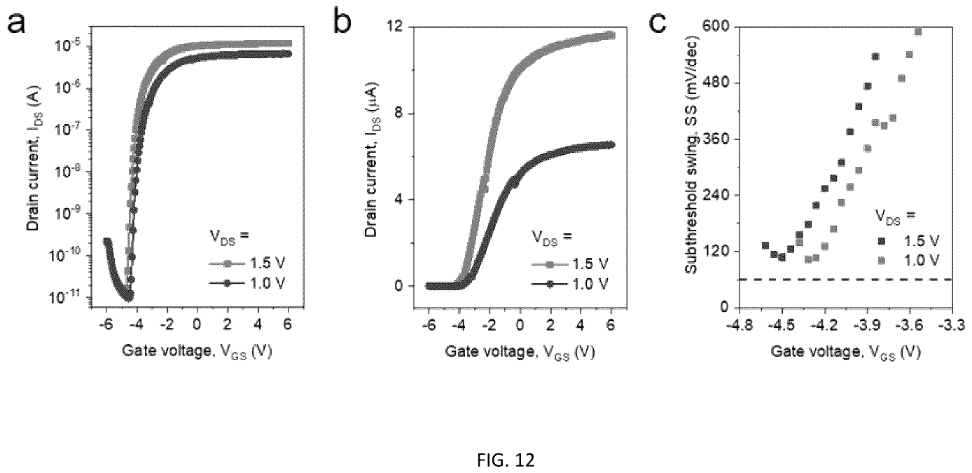

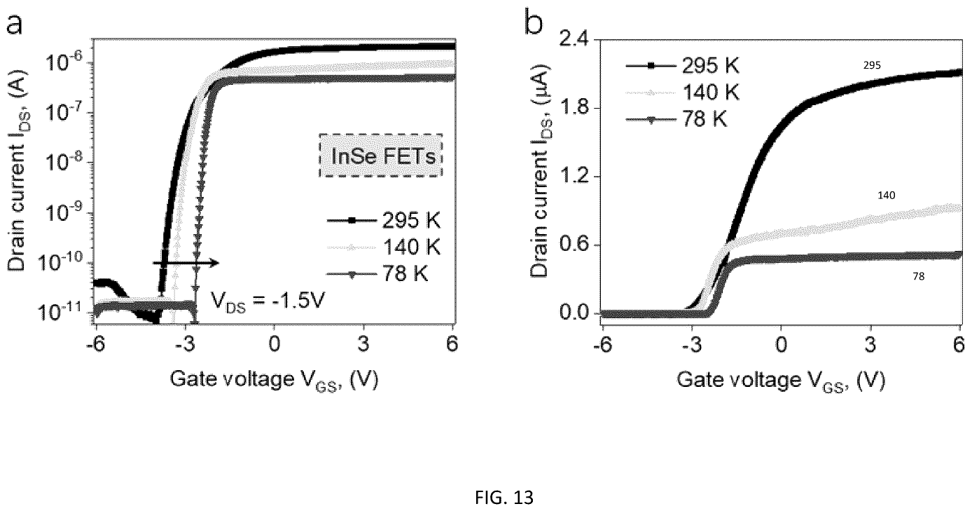

Section S4. Control InSe MOSFETs and their temperature dependent transport properties. See FIGS. 12-13.

### REFERENCES

1. Mudd, G. W.; Svatek, S. A.; Hague, L.; Makarovsky, O.; Kudrynskyi, Z. R.; Mellor, C. J.; Beton, P. H.; Eaves, L.; Novoselov, K. S.; Kovalyuk, Z. D.; Vdovin, E. E.; Marsden, A. J.; Wilson N. R.; Patané, A., High Broad-Band Photoresponsivity of Mechanically Formed InSe-Graphene van der Waals Heterostructures. Advanced Materials: 2015; Vol. 27, pp 3760-3766.
2. Braunstein, Moore, and Herman in C. Penn, T. Frommherz, and G. Bauer, Properties of Silicon Germanium and SiGe: Carbon EMIS Datareviews Series, no. 24, chapter 4.1
3. Tashmukhamedova, D. A., Yusupjanova, M. B. Emission and Optical Properties of SiO2/Si Thin Films. Journal of Surface Investigation: X-ray, Synchrotron and Neutron Techniques: 2016; Vol. 10, No. 6, pp. 1273-1275.
4. Mudd, G. W.; Svatek, S. A.; Ren, T.; Patané, A.; Makarovsky, O.; Eaves, L.; Beton, P. H.; Kovalyuk, Z. D.; Lashkarev, G. V.; Kudrynskyi, Z. R.; Dmitriev, A. I., Tuning the Bandgap of Exfoliated InSe Nanosheets by Quantum Confinement. Advanced Materials: 2013; Vol. 25, pp 5714-5718.
5. G. Neudeck. The PN Junction Diode (Addison-Wesley Publishing Co., Reading, Massachusetts, 1989)
6. Politano, A.; Campi, D.; Cattelan, M.; Ben Amara, I.; Jaziri, S.; Mazzotti, A.; Barinov, A.; Gurbulak, B.; Duman, S.; Agnoli, S.; Caputi, L. S.; Granozzi, G.; Cupolillo, A. Indium selenide: an insight into electronic band structure and surface excitations Scientific Reports 2017, 7.
7. Schaffler, Properties of Advanced Semiconductor Materials GaN, AlN, InN, BN, SiC, SiGe, John Wiley & Sons, Inc., New York, pp. 149-188, 2001
8. Wang, Q.; Han, L.; Wu, L.; Zhang, T.; Li, S.; Lu, P. Strain Effect on Thermoelectric Performance of InSe Monolayer. Nanoscale Research Letters 2019, 14.
9. Glasbrenner and Slack, Phys. Rev., 164, 4A, pp 1058-1069, 1964
10. Zhu, W.; Zheng, G.; Cao, S.; He, H. Thermal conductivity of amorphous SiO2 thin film: A molecular dynamics study. Scientific Reports 2018, 8.
11. Tyurin, A. V.; Gavrichev, K. S.; Zlomanov, V. P. Low-Temperature Heat Capacity and Thermodynamic Properties of InSe. Inorganic Materials 2007, 43, (9), 921-925.
12. Segura, A. Layered Indium Selenide under High Pressure: A Review. Crystals 2018, 8, (5).
13. Silicon—Band structure and carrier concentration. ioffe.ru.
14. König D., Rennau, M., Henker, M. Direct tunneling effective mass of electrons determined by intrinsic charge-up process. Solid State Electronics 2007, 51, pp 650-654.
15. Vexler, M. I.; Tyaginov, S.; Shulekin, A. F. Determination of the hole effective mass in thin silicon dioxide film by means of an analysis of characteristics of a MOS tunnel emitter transistor. Journal of Physics Condensed Matter 2005, 17, (50).

### Aspects

The following Aspects are illustrative only and do not limit the scope of the present disclosure or the appended claims. Any part or parts of any one or more Aspects can be combined with any part or parts of any one or more other Aspects.

Aspect 1. A tunnelling field-effect transistor, comprising: an active portion comprising one or more layers of a 2-D crystalline material; a semiconducting substrate, the active portion being superposed over the semiconducting substrate, and the semiconducting substrate being 3-D crystalline in nature; a source (e.g., a source electrode) in electronic communication with the active portion; a drain electrode in electronic communication with the active portion; and a gate electrode.

An example, non-limiting transistor configuration is provided in FIG. 1a. As shown, a transistor can include an active portion (InSe, in this instance), with a gate dielectric (AlOₓ, in this instance) and a gate (Ti/Au, in this instance—as shown, the gate can include a portion of Au and a portion of Ti) superposed on and in electronic communication with the active portion, the gate dielectric being superposed over the active portion, and the gate being superposed over the gate dielectric. As shown, a transistor can also include one or more drain electrodes in electronic communication with the active portion. As shown, a drain electrode can be positioned atop the active portion. As shown in FIG. 1a, the source can be Si; an oxide (e.g., SiOₓ) can be disposed between the source and the active portion. The active portion can lie above (e.g., atop) the source, as shown in FIG. 1. In some embodiments, the source and/or the oxide portion contact a face of the active portion without also contacting a side (i.e., an edge or thickness) of the active portion.

Aspect 2. The transistor of Aspect 1, wherein the 2-D crystalline material of the active portion and the semiconducting substrate are lattice-matched to one another. By lattice-matched is meant that the atomic spacing in-plane of the 2-D crystalline material of the active portion and the semiconducting substrate are within about 10% difference of one another.

Aspect 3. The transistor of any one of Aspects 1-2, further comprising a gate dielectric disposed between the gate electrode and the active portion.

Aspect 4. The transistor of Aspect 3, wherein the gate dielectric comprises AlOₓ, SiOx, HfOₓ, ZrOₓ, or any combination thereof.

Aspect 5. The transistor of any one of Aspects 1-4, wherein the 2-D crystalline material comprises InSe, WSe₂, Molybdenum Selenide (MoSe₂), Tin Selenide (SnSe₂), Gallium Selenide (GaSe), Molybdenum Telluride (MoTe₂), Di-Indium-Tri Selenide (In₂Se₃), or any combination thereof.

Aspect 6. The transistor of any one of Aspects 1-5, wherein the semiconducting substrate comprises Si (the Si optionally being single-crystal Si), Gallium Nitride (GaN), Silicon Carbide (SiC), Gallium Oxide (Ga₂O₃), Gallium Arsenide (GaAs), Indium Phosphide (InP), Gallium Phosphide (GaP), diamond (C), and combinations thereof.

Aspect 7. The transistor of any one of Aspects 1-6, further comprising a material disposed between the semiconducting substrate and the active portion, the material optionally comprising SiOₓ, e.g., SiO₂. Other suitable materials include, e.g., SiNx, AlOx, hexagonal boron nitride, HfOx, and/or ZrOx.

Aspect 8. The transistor of any one of Aspects 1-7, wherein one or more of the source electrode, the drain electrode, or the gate electrode comprises Ti, Au, Ni, Pt, Pd, graphene, or any combination thereof.

Aspect 9. The transistor of any one of Aspects 1-8, wherein the active portion defines a thickness in the range of from about 1 nm to about 20 nm. Thicknesses of about 1 to about 20 nm, about 2 to about 19 nm, about 3 to about 18 nm, about 4 to about 17 nm, about 5 to about 16 nm, about 6 to about 15 nm, about 7 to about 14 nm, about 8 to about 13 nm, about 9 to about 12 nm, or from about 10 to about 11 nm (and all subranges and combined ranges) are suitable.

Aspect 10. The transistor of any one of Aspects 1-9, wherein the transistor exhibits an average subthreshold swing of less than about 60 mV/decade over 5 orders of magnitude of drain current at room temperature. The transistor can exhibit an average subthreshold swing of less than about 60 mV/decade, less than about 55 mV/decade, less than about 50 mV/decade, less than about 45 mV/decade, less than about 40 mV/decade, less than about 35 mV decade, less than about 30 mV/decade, less than about 25 mV/decade, less than about 20 mV/decade, less than about 15 mV/decade, less than about 10 mV/decade, or even less than about 5 mV/decade over 5 orders of magnitude of drain current at room temperature.

Aspect 11. The transistor of Aspect 10, wherein the transistor exhibits an average subthreshold swing of less than about 60 mV/decade over 4 orders of magnitude of drain current at room temperature.

Aspect 12. The transistor of any one of Aspects 1-11, wherein the transistor exhibits an average subthreshold swing of less than about 60 mV/decade over a drain current of between about 10⁻¹² μA/μm and 10⁻⁸ μA/μm (e.g., from about 10⁻¹² and 10⁻⁸, or 10⁻¹¹ and 10⁻⁹, or 10⁻¹⁰ μA/μm) at room temperature.

Aspect 13. The transistor of any one of Aspects 1-12, wherein the transistor exhibits an average subthreshold swing of less than about 60 mV/decade at a drain current of less than about 10⁻⁸ μA/μm at room temperature

Aspect 14. The transistor of any one of Aspects 1-13 wherein the transistor exhibits an I₆₀/I_{OFF} ratio of at least about 10³. The I₆₀/I_{OFF} ratio can be, e.g., from about 10³ to about 10⁶, and all intermediate values and subranges. For example, the I₆₀/I_{OFF} ratio can be, e.g., from about 10³ to about 10⁶, from about 10⁴ to about 10⁶, from about 10⁵ to about 10⁶, from about 10³ to about 10⁵, from about 10³ to about 10⁴, or even from about 10³ to about 10⁴.

Aspect 15. The transistor of any one of Aspects 1-14, wherein the transistor exhibits a minimum subthreshold swing of less than about 10 μA/μm.

Aspect 16. The transistor of any one of Aspects 1-15, wherein the transistor exhibits an on/off current ratio of up to 10⁶ or 10⁷. The on/off current ratio can be, e.g., from about 10³ (or about 10¹ or about 10²) to about 10⁷, and all intermediate values and subranges. For example, the on/off current ratio can be, e.g., from about 10³ to about 10⁷, from about 10³ to about 10⁶, from about 10³ to about 10⁵, from about 10³ to about 10⁴, from about 10⁴ to about 10⁷, from about 10⁴ to about 10⁶, from about 10⁴ to about 10⁵, from about 10⁵ to about 10⁷, from about 10⁵ to about 10⁶, from about 10⁶ to about 10⁷.

Aspect 17. The transistor of any one of Aspects 1-16, wherein the wherein the transistor exhibits a subthreshold swing that is essentially temperature-invariant from between about 60 K to about 300 K, e.g., from about 60 K to about 300 K, from about 60 K to about 250 K, from about 60 K to about 200 K, from about 60 K to about 150 K, or even from about 60 K to about 100 K.

Aspect 18. A method, comprising operating a transistor according to any one of Aspects 1-17. Operating can include, e.g., communicating an electric current to the transistor.

Aspect 19. A device, the device comprising a transistor according to any one of Aspects 1-17, the device optionally being characterized as a logic device.

Aspect 20. A method, comprising fabricating a transistor according to any one of Aspects 1-17.

1. A tunnelling field-effect transistor, comprising:
an active portion comprising one or more layers of a 2-D crystalline material;
a semiconducting substrate,
the active portion being superposed over the semiconducting substrate, and
the semiconducting substrate being 3-D crystalline in nature;
a source electrode in electronic communication with the active portion;
a drain electrode in electronic communication with the active portion; and
a gate electrode.

2. The transistor of claim 1, wherein the 2-D crystalline material of the active portion and the semiconducting substrate are lattice-matched to one another.

3. The transistor of claim 1, further comprising a gate dielectric disposed between the gate electrode and the active portion.

4. The transistor of claim 3, wherein the gate dielectric comprises AlOₓ, SiOx, HfOₓ, ZrOₓ, or any combination thereof.

5. The transistor of claim 1, wherein the 2-D crystalline material comprises InSe, WSe₂, MoSe₂, SnSe₂, GaSe, MoTe₂, In₂Se₃, or any combination thereof.

6. The transistor of claim 1, wherein the semiconducting substrate comprises Si, the Si optionally being single-crystal Si, GaN, SiC, Ga₂O₃, GaAs, InP, GaP, C, or any combination thereof.

7. The transistor of claim 1, further comprising a material disposed between the semiconducting substrate and the active portion, the material optionally comprising SiO₂.

8. The transistor of claim 1, wherein one or more of the source electrode, the drain electrode, or the gate electrode comprises Ti, Au, Ni, Pt, Pd, graphene, or any combination thereof.

9. The transistor of claim 1, wherein the active portion defines a thickness in the range of from about 1 nm to about 20 nm.

10. The transistor of claim 1, wherein the transistor exhibits an average subthreshold swing of less than about 60 mV/decade over 5 orders of magnitude of drain current at room temperature.

11. The transistor of claim 10, wherein the transistor exhibits an average subthreshold swing of less than about 60 mV/decade over 4 orders of magnitude of drain current at room temperature.

12. The transistor of claim 1, wherein the transistor exhibits an average subthreshold swing of less than about 60 mV/decade over a drain current of between about 10⁻¹² μA/μm and 10⁻⁸ μA/μm at room temperature.

13. The transistor of claim 1, wherein the transistor exhibits an average subthreshold swing of less than about 60 mV/decade at a drain current of less than about 10⁻⁸ μA/μm at room temperature.

14. The transistor of claim 1, wherein the transistor exhibits an I₆₀/I_{OFF} ratio of at least about 10³.

15. The transistor of claim 1, wherein the transistor exhibits a minimum subthreshold swing of less than about 10 μA/μm.

16. The transistor of claim 1, wherein the transistor exhibits an on/off current ratio of up to about 10⁷.

17. The transistor of claim 1, wherein the wherein the transistor exhibits a subthreshold swing that is essentially temperature-invariant from between about 60 K to about 300 K.

18. A method, comprising operating a transistor according to claim 1.

19. A device, the device comprising a transistor according to claim 1, the device optionally being characterized as a logic device.

20. A method, comprising fabricating a transistor according to claim 1.
